(19) United States
(12) Patent Application Publication
(10) Pub. No.: US 2020/0075644 A1
(43) Pub. Date: Mar. 5, 2020

(54) SOLID-STATE IMAGING DEVICE

(71) Applicant: OLYMPUS CORPORATION, Tokyo (JP)

(72) Inventors: Jun Aoki, Tokyo (JP); Yusaku Koyama, Tokyo (JP)

(73) Assignee: OLYMPUS CORPORATION, Tokyo (JP)

(21) Appl. No.: 16/675,410

(22) Filed: Nov. 6, 2019

Related U.S. Application Data
(63) Continuation of application No. PCT/JP2017/018015, filed on May 12, 2017.

(51) Int. Cl. H01L 27/146; H04N 5/369

(52) U.S. Cl. CPC H01L 27/1463; H01L 27/14612; H04N 5/379; H01L 27/14643; H01L 27/14641; H01L 27/14621

(57) ABSTRACT

A solid-state imaging device includes a two-dimensional pixel array in which unit pixels are arranged on a semiconductor substrate, each including a photoelectric conversion element, and a circuit element. When a plurality of adjacent unit pixels are defined as one pixel group set, a plurality of pixel group sets are arranged in the two-dimensional pixel array. In the one pixel group set, a periphery of the one pixel group set is surrounded by an insulating element isolation region that isolates elements in the semiconductor substrate, except for an intermediate portion between two adjacent unit pixels. In the one pixel group set, two adjacent photoelectric conversion elements are arranged so that two floating diffusions respectively connected to the two adjacent photoelectric conversion elements are opposed to each other with the circuit element interposed therebetween. A transistor shared by the one pixel group set is provided in the intermediate portion.

### CROSS REFERENCE TO RELATED APPLICATIONS

This application is a continuation application based on a PCT Patent Application No. PCT/JP2017/018015, filed on May 12, 2017, the content of which is incorporated herein by reference.

### BACKGROUND

### Technical Field

The present invention relates to a solid-state imaging device. More specifically, the present invention relates to a solid-state imaging device in which a plurality of unit pixels are arranged in a two-dimensional matrix on a semiconductor substrate.

### Background Art

In general, in a solid-state imaging device or an image sensor, signal charges generated and accumulated by photoelectric conversion elements of pixels on which light is incident are guided to an amplifying unit provided in the pixel, and a signal amplified by the amplifying unit is output from the pixel. Some solid-state imaging devices and image sensors using a semiconductor substrate include a pixel array in which a plurality of unit pixels are arranged in a two-dimensional matrix on the semiconductor substrate. In such a solid-state imaging device or image sensor, in order to reduce electrical and optical crosstalk between adjacent pixels, that is, color mixing, for example, Japanese Unexamined Patent Application, First Publication No. 2009-206356 (hereinafter referred to as Patent Document 1) discloses a configuration (Full Deep Trench Isolation (FDTI)) in which a groove is provided in an insulating layer between adjacent pixels from the front surface to the back surface of the silicon layer of the semiconductor substitute.

FIG. 4 is a cross-sectional view illustrating a configuration of a pixel array in the solid-state imaging device of Patent Document 1. As shown in FIG. 4, in the semiconductor substrate 404, a plurality of unit pixels 1 are arranged in a two-dimensional matrix. On the front surface of the semiconductor substrate 404, the unit pixel 1 includes a wiring layer 402 provided in the interlayer insulating film 409. On the back surface of the semiconductor substrate 404, the unit pixel 1 includes a diffusion layer 403 that accumulates signal charges, an antireflection film 405, a color filter 406, a microlens 407, and an element isolation insulating film 408.

The element isolation insulating film 408 is provided at a boundary portion between adjacent unit pixels 1 on the semiconductor substrate 404 and insulates the unit pixels 1 from each other. The element isolation insulating film 408 is formed of an insulating film having a refractive index lower than that of the silicon layer of the semiconductor substrate 404.

In Patent Document 1, the color filter 406 of each unit pixel 1 is one of a color filter R that transmits light in the red wavelength region, a color filter G that transmits light in the green wavelength region, and a color filter B that transmits light in the blue wavelength region. Here, the unit pixel 1 having the color filter R is represented as R pixel, the unit pixel 1 having the color filter G is represented as G pixel, and the unit pixel 1 having the color filter B is represented as B pixel. Each of the R pixel, the G pixel, and the B pixel is insulated by an element isolation insulating film 408.

FIG. 5 is a plan view showing a configuration of a pixel array in the solid-state imaging device of Patent Document 1. FIG. 4 is a cross-sectional view taken along line VI-VI in FIG. 5. As shown in FIG. 5, a plurality of unit pixels 1 are arranged in a two-dimensional matrix on a semiconductor substrate 404. Each unit pixel 1 is insulated from each other by being surrounded by an element isolation insulating film 408 on all sides.

In the configuration of the pixel array of Patent Document 1, since the unit pixels 1 are insulated from each other by the element isolation insulating film 408, crosstalk and color mixing between unit pixels can be effectively prevented. However, in the configuration in which the groove of the insulating layer is provided between all adjacent unit pixels in this way, each unit pixel 1 is configured to be completely surrounded by the element isolation insulating film 408. Therefore, in each unit pixel 1, a transistor (for example, a reset transistor, an amplifier transistor, and a selection transistor) for driving the pixel must also be disposed inside the region surrounded by the element isolation insulating film 408. Therefore, in each unit pixel 1, the arrangement and size of the transistor are restricted.

Furthermore, in the configuration of the pixel array of Patent Document 1, since it is necessary to arrange the transistor inside the region surrounded by the element isolation insulating film 408, the area or the shape of the arranged photodiode is limited.

### SUMMARY

The present invention provides a solid-state imaging device capable of preventing crosstalk and color mixing while relaxing restrictions on transistor arrangement and size in a pixel array on a semiconductor substrate.

According to an aspect of the present invention, a solid-state imaging device includes a two-dimensional pixel array in which unit pixels are arranged on a semiconductor substrate, each of the unit pixels including a photoelectric conversion element that converts incident light into an electrical signal, and a circuit element that reads out the electrical signal that has been converted. When a plurality of adjacent unit pixels are defined as one pixel group set, a plurality of pixel group sets are arranged in the two-dimensional pixel array. In the one pixel group set, a periphery of the one pixel group set is surrounded by an insulating element isolation region that isolates elements in the semiconductor substrate, except for an intermediate portion between two adjacent unit pixels. In the one pixel group set, two adjacent photoelectric conversion elements are arranged so that two floating diffusions respectively connected to the two adjacent photoelectric conversion elements are opposed to each other with the circuit element interposed therebetween. A transistor shared by the one pixel group set is provided in the intermediate portion.

In the one pixel group set, the element isolation region may be separated at a portion where crossing a straight line along the intermediate portion of the plurality of adjacent unit pixels, and a width at which the element isolation region is separated is larger than a width of an active area of the circuit element.

When a surface on which the photoelectric conversion element and the circuit element of the semiconductor substrate are arranged is defined as a front surface of the semiconductor substrate, and a surface on an opposite side is defined as a back surface of the semiconductor substrate, the element isolation region may penetrate from the front surface to the back surface of the semiconductor substrate, and the incident light may enter from a side of the back surface of the semiconductor substrate.

The circuit element may be disposed at a portion where the element isolation region is separated.

A transistor shared by the one pixel group set may be any one of an amplifier transistor, a reset transistor, and a selection transistor.

According to the solid-state imaging device of each aspect described above, it is possible to provide a solid-state imaging device capable of preventing crosstalk and color mixing while relaxing restrictions on transistor arrangement and size in the pixel array on the semiconductor substrate.

### BRIEF DESCRIPTION OF THE DRAWINGS

FIG. 1 is a plan view showing a configuration of a pixel array in a solid-state imaging device according to a first embodiment of the present invention.

FIG. 2A is a plan view showing a configuration of a pixel array in a solid-state imaging device according to a second embodiment of the present invention.

FIG. 2B is a cross-sectional view illustrating a configuration of a pixel array in a solid-state imaging device according to a second embodiment of the present invention.

FIG. 2C is a cross-sectional view illustrating a configuration of a pixel array in a solid-state imaging device according to a second embodiment of the present invention.

FIG. 3 is a plan view showing a configuration of a pixel array in a solid-state imaging device according to a third embodiment of the present invention.

FIG. 4 is a cross-sectional view illustrating a configuration of a pixel array in a solid-state imaging device according to a conventional art.

FIG. 5 is a plan view showing a configuration of a pixel array in a solid-state imaging device according to a conventional art.

### DETAILED DESCRIPTION OF THE PREFERRED EMBODIMENTS

Hereinafter, embodiments of the present invention will be described with reference to the drawings. The following description of the embodiments is intended to specifically describe the invention defined in the claims, and is not intended to limit the invention defined in the claims.

### First Embodiment

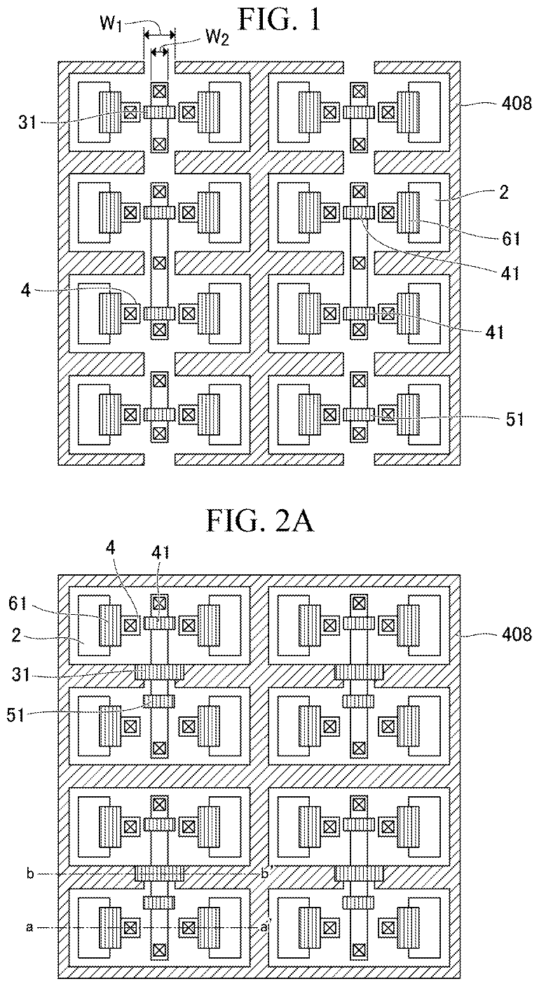

A first embodiment of the present invention will be described. FIG. 1 is a plan view showing a configuration of a pixel array in the solid-state imaging device according to the first embodiment of the present invention. In the pixel array, unit pixels are two-dimensionally arranged on the semiconductor substrate 404. In FIG. 1, 16 unit pixels of “4 pixels in the horizontal direction”×“4 pixels in the vertical direction” are arranged.

The element isolation insulating film (element isolation region) 408 is formed of an insulating film having a refractive index lower than that of the silicon layer of the semiconductor substrate. In Patent Document 1, the element isolation insulating film 408 is provided at all boundary portions between adjacent unit pixels on the semiconductor substrate. However, in the first embodiment of the present invention, as shown in FIG. 1, among the element isolation insulating film 408 surrounding each unit pixel, the element isolation insulating film 408 of one side separating adjacent unit pixels and the element isolation insulating film 408 positioned at a portion where crossing the extension line of the one side are omitted.

That is, as shown in FIG. 1, the element isolation insulating film 408 is separated by the width W1. In FIG. 1, the element isolation insulating film 408 positioned above the amplifier transistor 31 and below the selection transistor 51 is also separated by the width W1, but the element isolation insulating film 408 positioned at these portions may not be separated.

In the configuration of FIG. 1, the photodiode 2 included in each unit pixel is rectangular, and is arranged so that three directions of four sides of the photodiode 2 are surrounded by the element isolation insulating film 408. The floating diffusion 4 is connected to the side not surrounded by the element isolation insulating film 408 among the four sides of the photodiode 2 through the transfer transistor 61.

In the configuration of FIG. 1, various transistors other than the transfer transistor 61 are shared by eight unit pixels of “2 pixels in the horizontal direction”×“4 pixels in the vertical direction”. Various shared transistors are configured by an amplifier transistor 31, a reset transistor 41, a selection transistor 51, and the like. The floating diffusions 4 of the adjacent unit pixels are opposed to each other with various transistors other than the transfer transistor 61 and their active areas interposed therebetween. That is, each floating diffusion 4 is arranged so that two floating diffusions 4 respectively connected to two adjacent photodiodes 2 face each other across various transistors other than the transfer transistor 61 and their active areas. Various transistors other than the transfer transistor 61 and their active areas are arranged in the vertical direction at the intermediate portion between the floating diffusions 4 of adjacent unit pixels.

Here, the element isolation insulating film 408 is separated at a portion where crossing a straight line along the intermediate portion of the two floating diffusions 4 of adjacent unit pixels, and it is preferable that the width W1 where the element isolation insulating film 408 is separated is larger than the width W2 of the active area of various transistors other than the transfer transistor 61. That is, it is preferable that the width W1 that the element isolation insulating film 408 is separated is larger than the width W2 of the active area of various transistors other than the transfer transistor 61. As a result, various transistors can be arranged so as to cover the portion where the element isolation insulating film 408 is separated, so that the degree of freedom in layout and size of transistors is increased.

In the configuration of FIG. 1, two reset transistors 41 are shared by eight unit pixels, and this is in consideration of layout symmetry. One reset transistor 41 may be shared by eight unit pixels.

As described above, in the configuration of FIG. 1, three directions of the four sides of each photodiode 2 of the adjacent unit pixel are surrounded by the element isolation insulating film 408. In other words, the periphery of the photodiode 2 is surrounded by the element isolation insulating film 408 at least other than the intermediate portion between the two photodiodes 2 of the adjacent unit pixels. In other words, the photodiode 2 is surrounded b an element isolation insulating film 408 and circuit elements including various transistors.

Further, various transistors other than the transfer transistor 61 and their active areas are arranged so that the photodiodes 2 of adjacent unit pixels are not in contact with each other, and the photodiodes 2 of other unit pixels are separated by the element isolation insulating film 408. Therefore, crosstalk and color mixing between unit pixels can be prevented.

Further, various transistors other than the transfer transistor 61 and their active areas are shared by a plurality of unit pixels, and the various transistors other than the transfer transistor 61 and the element isolation insulating film 408 where their active areas are arranged are omitted. Therefore, restrictions on arrangement and size of various transistors can be relaxed.

Furthermore, since the various transistors except the transfer transistor 61 and their active areas are shared by a plurality of unit pixels, the area occupied by the various transistors per unit pixel can be reduced. As a result, the photodiode arrangement area can be expanded in the pixel array. Thereby, the area of the photodiode can be increased, and the number of full well capacity and the quantum efficiency of the pixel can be maintained to prevent image quality deterioration.

### Second Embodiment

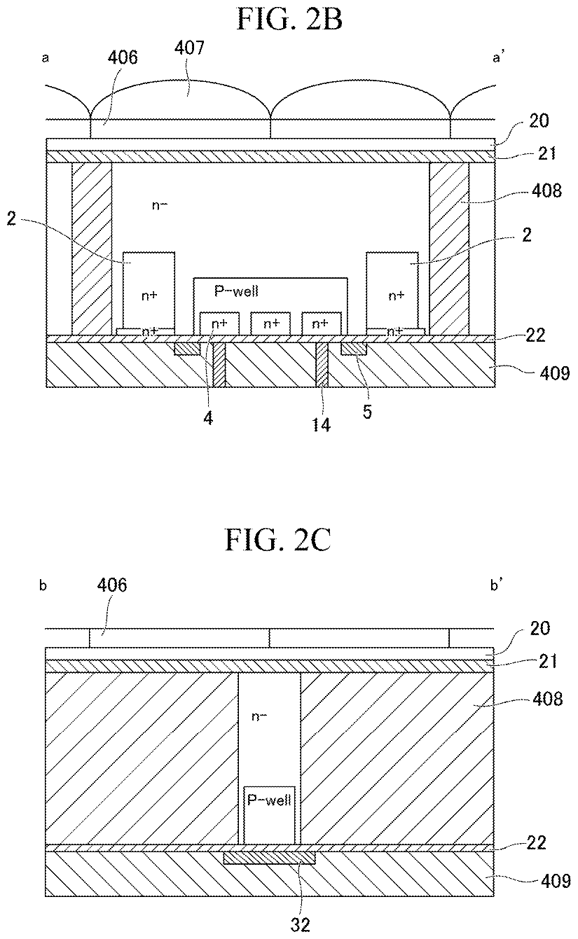

A second embodiment of the present invention will be described. FIG. 2A is a plan view showing the configuration of the pixel array in the solid-state imaging device according to the second embodiment of the present invention. As in FIG. 1, in the pixel array, unit pixels are two-dimensionally arranged on the semiconductor substrate 404, and 16 unit pixels of “4 pixels in the horizontal direction”×“4 pixels in the vertical direction” are arranged.

A difference from the configuration in FIG. 1 is that in FIG. 2A, four unit pixels of “2 pixels in the horizontal direction”×“2 pixels in the vertical direction” share various transistors. Therefore, as shown in FIG. 2A, among the element isolation insulating films 408 surrounding each unit pixel, the element isolation insulating film 408 of one side that separates adjacent unit pixels and the element isolation insulating film 408 positioned above or below the one side are omitted.

Also in the configuration of FIG. 2A, the photodiode 2 included in each unit pixel is rectangular, and is arranged so that three directions of the four sides of the photodiode 2 are surrounded by the element isolation insulating film 408. The floating diffusion 4 is connected to the side not surrounded by the element isolation insulating film 408 among the four sides of the photodiode 2 through the transfer transistor 61.

In the configuration of FIG. 2A, four unit pixels of “2 pixels in the horizontal direction”×“2 pixels in the vertical direction” share various transistors other than the transfer transistor 61. Various shared transistors are configured by an amplifier transistor 31, a reset transistor 41, a selection transistor 51, and the like. The floating diffusions 4 of the adjacent unit pixels are opposed to each other with various transistors other than the transfer transistor 61 and their active areas interposed therebetween. That is, each floating diffusion 4 is arranged so that two floating diffusions 4 respectively connected to two adjacent photodiodes 2 face each other across various transistors other than the transfer transistor 61 and their active areas. Various transistors other than the transfer transistor 61 and their active areas are arranged in the vertical direction at the intermediate portion between the floating diffusions 4 of adjacent unit pixels.

In the configuration of FIG. 2A, the element isolation insulating film 408 positioned on either upper or lower of the intermediate portion of the two floating diffusions 4 at a portion crossing a straight line along the intermediate portion of the two floating diffusions 4 of the adjacent unit pixels is separated. The width W1 at which the element isolation insulating film 408 is separated is preferably larger than the width W2 of the active area of various transistors other than the transfer transistor 61. That is, it is preferable that the width W1 that the element isolation insulating film 408 is separated is larger than the width W2 of the active area of various transistors other than the transfer transistor 61. As a result, various transistors can be arranged so as to cover the portion where the element isolation insulating film 408 is separated, so that the degree of freedom in layout and size of transistors is increased.

In the configuration of FIG. 2A, active areas of various transistors other than the transfer transistor 61 are arranged at portions where the element isolation insulating film 408 is separated, and the amplifier transistor 31 is arranged so as to overlap therewith. Here, the transistor disposed in the portion where the element isolation insulating film 408 is separated is not limited to the amplifier transistor 31. The reset transistor 41, the selection transistor 51, and the like may be disposed in a portion where the element isolation insulating film 408 is separated. That is, various transistors may be arranged at a portion where the element isolation insulating film 408 is separated.

As described above, by arranging various transistors in the portion where the element isolation insulating film 408 is separated, the area occupied by the various transistors per unit pixel can be reduced. As a result, in the pixel array, restrictions on the arrangement and size of various transistors can be relaxed. In addition, since the arrangement area of the photodiode can be increased, the area of the photodiode can be increased.

As described above, in the configuration of FIG. 2A, various transistors other than the transfer transistor 61 and their active areas are arranged so that the photodiodes 2 of adjacent unit pixels are not in contact with each other, and the photodiodes 2 of other unit pixels are separated from each other by an element isolation insulating film 408. Therefore, crosstalk and color mixing can be prevented.

Further, various transistors other than the transfer transistor 61 and their active areas are shared by a plurality of unit pixels, and the element isolation insulating film 408 where the various transistors other than the transfer transistor 61 and their active areas are arranged are omitted. Therefore, restrictions on arrangement and size of various transistors can be relaxed.

Furthermore, since the various transistors except the transfer transistor 61 and their active areas are shared by a plurality of unit pixels, the area occupied by the various transistors per unit pixel can be reduced. As a result, the photodiode arrangement area can be expanded in the pixel array. Thereby, the area of the photodiode can be increased, and the number of full well capacity and the quantum efficiency of the pixel can be maintained to prevent image quality deterioration.

FIGS. 2B and 2C are cross-sectional views illustrating the configuration of the pixel array in the solid-state imaging device according to the second embodiment of the present invention. Specifically, FIG. 2B is a diagram showing a cross section taken along line a-a′ of FIG. 2A. FIG. 2C is a diagram showing a cross section taken along line b-b′ of FIG. 2A. In the configuration of FIG. 2B, a circuit portion (circuit element) is formed on the front surface side (lower side of the drawing) of the semiconductor substrate, and the gate insulating film 22 and the interlayer insulating film 409 are formed so as to cover the front surface of the semiconductor substrate and the circuit portion. Further, the back surface side (upper side in the drawing) of the semiconductor substrate is a light receiving surface, where the insulating film 21 and the planarizing film 20 are formed, and the color filter 406 and the microlens 407 are disposed.

As described above, when a surface of the semiconductor substrate on which the photodiode and the circuit unit are disposed is referred to as the front surface of the semiconductor substrate and a surface on the opposite side is referred to as the back surface of the semiconductor substrate, the incident light is incident from the back surface side of the semiconductor substrate. The circuit unit includes various transistors.

In FIGS. 2B and 2C, the element isolation insulating film 408 is drawn so as to penetrate from the front surface to the back surface of the semiconductor substrate, but the element isolation insulating film 408 may not penetrate from the front surface to the back surface of the semiconductor substrate. The same applies to other embodiments.

The semiconductor substrate is divided into regions insulated from each other the element isolation insulating film 408. On the front surface side of the semiconductor substrate (downward in the figure), a contact 14 is provided so as to penetrate through the interlayer insulating film 409 from the floating diffusion 4 to downward. As shown in FIG. 2B, the transfer transistor gate 5 of the transfer transistor 61 is provided in the interlayer insulating film 409 on the line a-a′ in FIG. 2A. As shown in FIG. 2C, the element isolation insulating film 408 is separated on the line b-b′ of FIG. 2A, and the amplifier transistor gate 32 of the amplifier transistor 31 is provided at a portion overlapping the separating portion.

### Third Embodiment

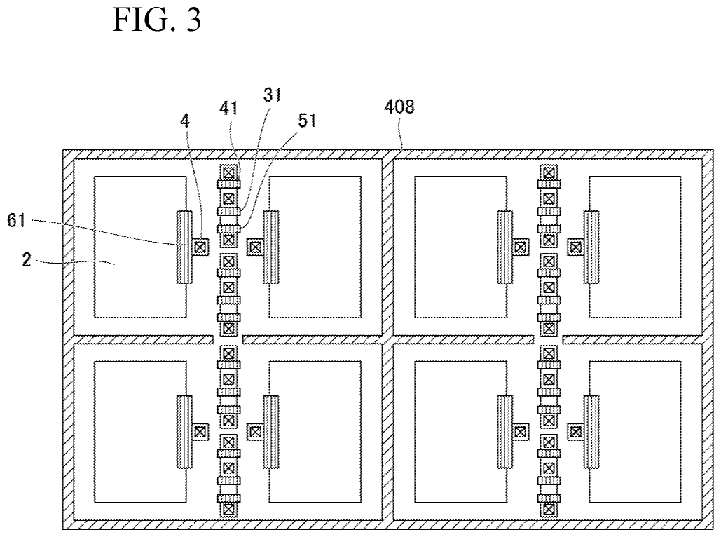

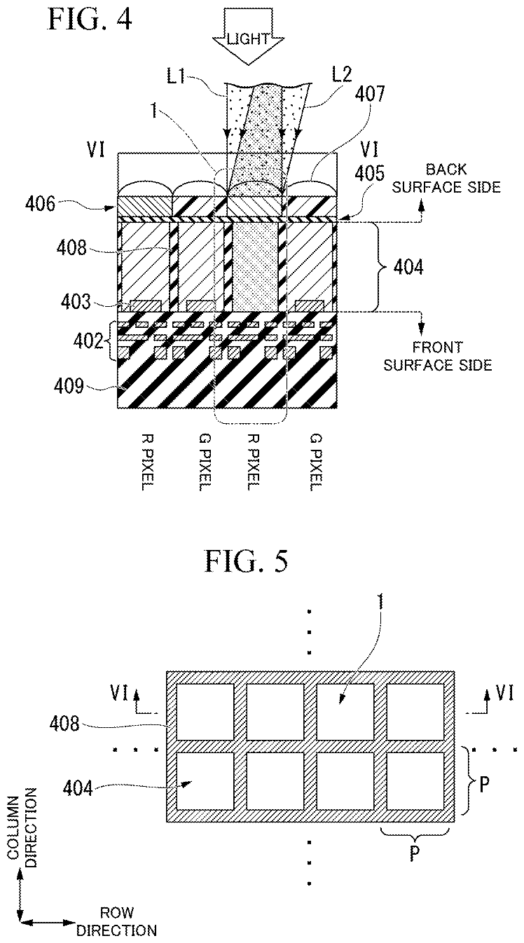

A third embodiment of the present invention will be described. FIG. 3 is a plan view showing the configuration of the pixel array in the solid-state imaging device according to the third embodiment of the present invention. In FIG. 3, in the pixel array, unit pixels are two-dimensionally arranged on the semiconductor substrate 404, and eight unit pixels of “2 pixels in the horizontal direction”×“4 pixels in the vertical direction” are arranged. The form of the element isolation insulating film 408 in the configuration of FIG. 3 is the same as the form of the element isolation insulating film 408 in FIG. 2A.

The difference from the configuration of FIG. 2A is that in the configuration of FIG. 3, various transistors and their active areas are not shared between unit pixels. In the configuration of FIG. 3, various transistors other than the transfer transistor 61 and their active areas are arranged in the vertical direction at intermediate portions of the floating diffusions 4 of adjacent unit pixels, as in the configuration of FIG. 2A. However, since various transistors and their active areas are not shared between unit pixels, the number of various transistors such as the amplifier transistor 31, the reset transistor 41, and the selection transistor 51 and their active areas are arranged as many as the number of unit pixels.

Also in the configuration of FIG. 3, the photodiode 2 included in each unit pixel is rectangular, and is arranged so that three directions of the four sides of the photodiode 2 are surrounded by the element isolation insulating film 408. The floating diffusion 4 is connected to the side not surrounded by the element isolation insulating film 408 among the four sides of the photodiode 2 through the transfer transistor 61.

As described above, in the configuration of FIG. 3, various transistors other than the transfer transistor 61 and their active areas are arranged so that the photodiodes 2 of adjacent unit pixels do not contact each other, and the photodiodes 2 of the other unit pixels are separated by the element isolation insulating film 408. Therefore, crosstalk and color mixing can be prevented.

Further, various transistors other than the transfer transistor 61 and the element isolation insulating film 408 at portions where the active areas are arranged are omitted. Therefore, restrictions on transistor arrangement and size can be relaxed. Further, the area occupied by various transistors per unit pixel can be reduced. As a result, the photodiode arrangement area can be expanded in the pixel array. As a result, the area of the photodiode can be increased, and the number of full well capacity and the quantum efficiency of the pixel can be maintained to prevent image quality deterioration.

Furthermore, unlike the configurations of FIGS. 1 and 2A, in the configuration of FIG. 3, various transistors and their active areas are not shared between unit pixels, it is possible to prevent signal cross-talk between pixels and to speed up processing.

As described above, although preferable embodiment of the present invention has been described, the present invention is not limited to these embodiment and their modification. Additions, omissions, substitutions, and other modifications can be made without departing from the scope of the present invention. For example, the number of unit pixels sharing various transistors can be any number. Further, the configuration of various transistors in the unit pixel is not limited to the above embodiment.

In the present specification, words indicating directions such as “front, back, above, below, right, left, vertical, horizontal, row and column” are used to describe these directions in the device of the present invention. Accordingly, these terms used to describe the specification of the present invention should be interpreted relatively in the device of the present invention.

The present invention can be applied to various solid-state imaging devices, and can efficiently prevent crosstalk and color mixing between adjacent pixels.

What is claimed is:

1. A solid-state imaging device comprising a two-dimensional pixel array in which unit pixels are arranged on a semiconductor substrate, each of the unit pixels including a photoelectric conversion element that converts incident light into an electrical signal, and a circuit element that reads out the electrical signal that has been converted,
wherein, when a plurality of adjacent unit pixels are defined as one pixel group set, a plurality of pixel group sets are arranged in the two-dimensional pixel array,
in the one pixel group set, a periphery of the one pixel group set is surrounded by an insulating element isolation region that isolates elements in the semiconductor substrate, except for an intermediate portion between two adjacent unit pixels,
in the one pixel group set, two adjacent photoelectric conversion elements are arranged so that two floating diffusions respectively connected to the two adjacent photoelectric conversion elements are opposed to each other with the circuit element interposed therebetween, and
a transistor shared by the one pixel group set is provided in the intermediate portion.

2. The solid-state imaging device according to claim 1, wherein,
in the one pixel group set, the element isolation region is separated at a portion where crossing a straight line along the intermediate portion of the plurality of adjacent unit pixels, and
a width at which the element isolation region is separated is larger than a width of an active area of the circuit element.

3. The solid-state imaging device according claim 1, wherein,
when a surface on which the photoelectric conversion element and the circuit element of the semiconductor substrate are arranged is defined as a front surface of the semiconductor substrate, and a surface on an opposite side is defined as a back surface of the semiconductor substrate,
the element isolation region penetrates from the front surface to the back surface of the semiconductor substrate, and
the incident light enters from a side of the back surface of the semiconductor substrate.

4. The solid-state imaging device according to claim 2, wherein the circuit element is disposed at a portion where the element isolation region is separated.

5. The solid-state imaging device according to claim 1, wherein a transistor shared by the one pixel group set is any one of an amplifier transistor, a reset transistor, and a selection transistor.
